(19) United States
(12) Patent Application Publication
(10) Pub. No.: US 2014/0002103 A1
(43) Pub. Date: Jan. 2, 2014

(54) CABLE DIAGNOSTIC DEVICE

(71) Applicant: YEN-CHANG HUANG, NEW TAIPEI CITY (TW)

(72) Inventor: YEN-CHANG HUANG, NEW TAIPEI CITY (TW)

(73) Assignee: HOBBES & CO., LTD., NEW TAIPEI CITY (TW)

(21) Appl. No.: 13/539,624

(22) Filed: Jul. 2, 2012

(51) Int. Cl. G01R 31/02

(52) U.S. Cl. 324/539

(57) ABSTRACT

A cable diagnostic device for diagnosing a plurality of conductive pins of cables is provided. The cable diagnostic device comprises a body unit, a diagnostic unit, a display unit, and a pair of diagnostic adaptor heads. The body unit has an accommodating space defined therein. The diagnostic unit is disposed in the accommodating space. The diagnostic unit includes a transmitting port and a receiving port. The display unit is visibly exposed from the body unit. The pair of diagnostic adaptor heads detachably disposed at the body unit, each of the diagnostic adaptor heads includes a diagnostic connector and a diagnostic socket. Whereby when the two diagnostic connectors are inserted into the transmitting port and receiving port respectively, two ends of the cable are plugged into the two diagnostic sockets respectively, the diagnostic unit diagnoses test pulses between the two ends of each conductive pins of the cable.

### BACKGROUND OF THE INVENTION

1. Field of the Invention

The present invention relates to a cable diagnosing device, in particular, to a cable diagnosing device having changeable adaptor heads capable of diagnosing cables having connectors of different styles/specifications.

2. Description of the Related Art

Many devices rely on various cables to connect each other. The qualified cable plays an important role. Conventional cable diagnosing devices can only accept a single type of cable. If the operator needs to diagnose multiple types of cables, the operator has to buy various cable diagnosing devices. Another conventional multi-function cable diagnosing devices having multiple types of sockets are able to diagnose multiple types of cables, but it is not necessary for the operator to check multiple types of cables at the same time, and the multi-function cable diagnosing devices are bulky not easy to carry.

Based on research, the inventor proposes the present invention to address the above issues.

### SUMMARY OF THE INVENTION

In view of the aforementioned issues, a cable diagnosing device is disclosed. The cable diagnosing device is capable of accommodating a pair of removable adaptor heads that are adapted to receive cable connectors of different styles/specifications, thus allowing the cable diagnosing to remain physically compact yet provide increased operational flexibility.

To achieve the above-mentioned objectives, the present invention is to provide a cable diagnosing device having changeable adaptor heads, thus providing flexible adaptability for cables having connectors of different styles. The cable diagnosing device includes a body unit having an accommodating space defined; a diagnostic unit disposed in the accommodating space of the body unit, the diagnostic unit including a transmitting port and a receiving port; wherein the transmitting port and the receiving port are electrically connected to the diagnostic unit; a display unit exposed out of the body unit; a pair of diagnostic adaptor heads detachably disposed at the body unit, each of the diagnostic adaptor heads including a diagnostic connector and a diagnostic socket. Whereby when the two diagnostic connectors are inserted into the transmitting port and receiving port respectively, two ends of the cable are plugged into the two diagnostic sockets, the diagnostic unit diagnoses test pulses between a plurality of conductive pins of the cable.

The instant disclosure has following benefits: First, the operator can insert a pair of various diagnostic adaptor heads into the cable diagnostic device corresponding to the diagnosed cable, that allows the cable diagnostic device miniaturization and easy to carry. Second, two ends of the diagnosed cable plugged into the two diagnostic sockets of the two diagnostic adaptor heads respectively brings fast check of the diagnosed cable, which is qualified or fail. Third, the cable diagnostic device can diagnose a plurality of conductive pins of the diagnosed cable in a one-on-one or a one-to-many manner by displayed on the display unit. Thus, the status of the conductive pins of the diagnosed cable (such as conduction, open, short, or cross-line) could be quickly determined by the display unit. The cause regarding the status of the conductive pins could be checked according to the display unit for fast diagnoses and maintains.

In order to further appreciate the characteristics and technical contents of the present invention, references are hereunder made to the detailed descriptions and appended drawings in connection with the present invention. However, the appended drawings are merely shown for exemplary purposes, rather than being used to restrict the scope of the present invention.

### BRIEF DESCRIPTION OF THE DRAWINGS

FIG. 1 is a schematic perspective view of the cable diagnostic device of the present invention;

FIG. 2 shows a exploded view of the cable diagnostic device of the present invention;

FIG. 3 shows a exploded view from another angle of the cable diagnostic device of the present invention;

FIG. 4 shows a perspective view illustrating a cable plugged into the cable diagnostic device of the present invention;

FIG. 5 shows a flowchart illustrating steps for diagnosing a cable status of a cable by the cable diagnostic device of the present invention;

FIG. 6 shows a perspective view illustrating a pair of diagnostic adaptor heads detachable from the cable diagnostic device of the present invention;

FIG. 7 shows a perspective view illustrating another pair of diagnostic adaptor heads detachable from the cable diagnostic device of the present invention;

### DETAILED DESCRIPTION OF THE PREFERRED EMBODIMENT

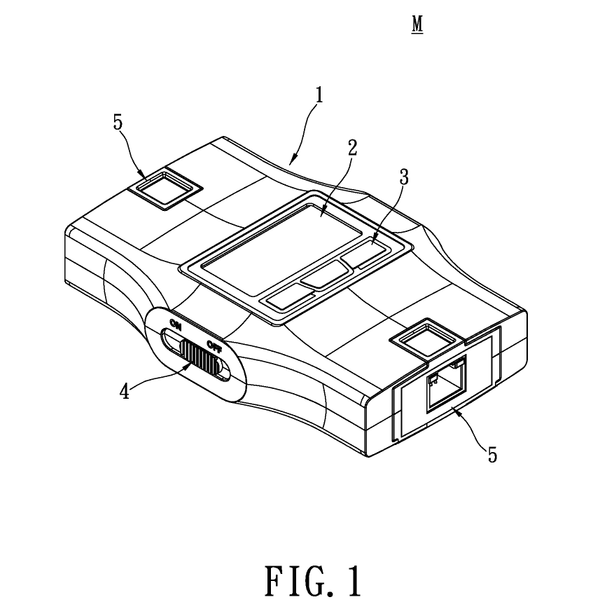

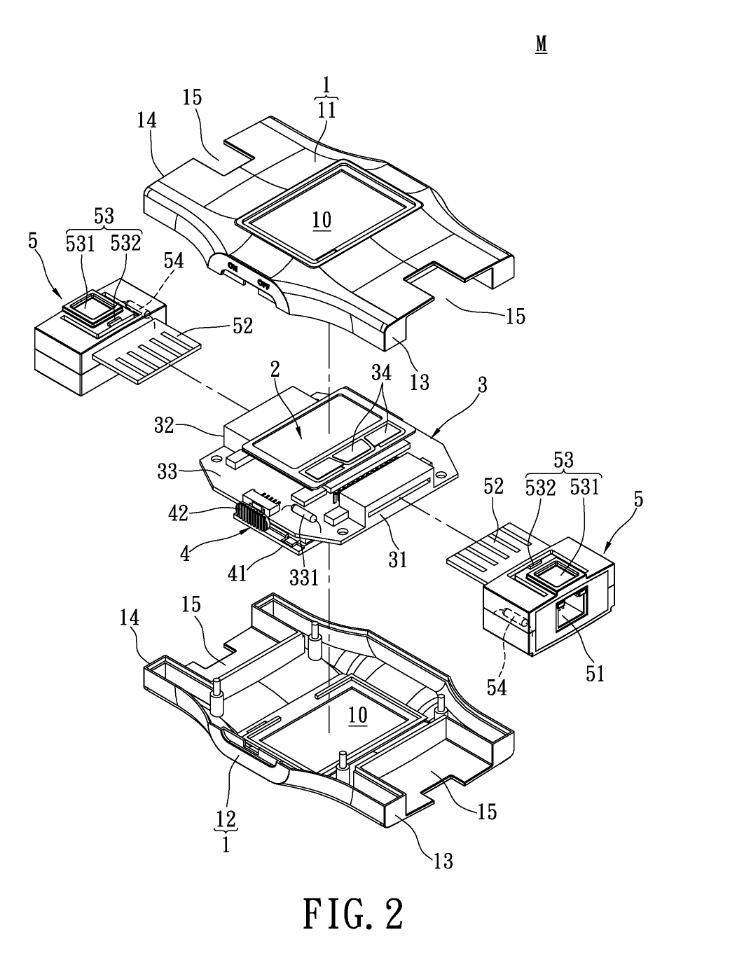

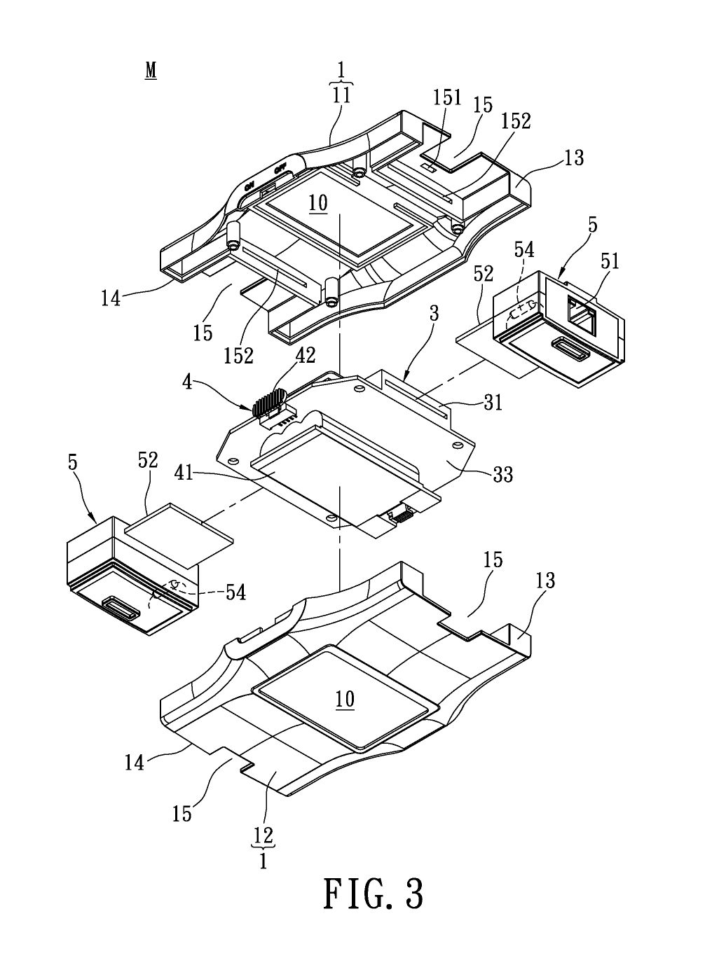

Referring now to FIGS. 1 to 4, a cable diagnostic device constructed in accordance with the invention is shown and generally designated as M. The cable diagnostic device M comprises a body unit 1, a display unit 2, a diagnostic unit 3, a power unit 4, and a pair of diagnostic adaptor heads 5.

The body unit 1 has an upper shell 11 and a lower shell 12; the upper shell 11 and the lower shell 12 jointly define an accommodating space 10 of the body unit 1; the upper shell 11 and the lower shell 12 jointly have a front end 13 and a rear end 14 of the body unit 1, and the rear end 14 is opposite to the front end 13. The body unit 1 is designed for the ease of handling single-handedly, providing the operator portability, easy handling and fast maintenance.

The diagnostic unit 3 is disposed in the accommodating space 10 of the body unit 1. The diagnostic unit 3 includes a transmitting port 31, a receiving port 32, a diagnostic circuit board 33, and a plurality of buttons 34; the transmitting port 31, the receiving port 32, and a plurality of the buttons 34 are electrically connected to the diagnostic circuit board 33.

The display unit 2 is electrically connected to the diagnostic circuit board 33 of the diagnostic unit 3 and visibly exposed from the body unit 1. Specifically, the display unit 2 is a display panel, or a plurality of indicators with indicating lights.

Both of the diagnostic adaptor heads 5 respectively include a diagnostic connector 52 and a diagnostic socket 51. One of the diagnostic connectors 52 is inserted into the transmitting port 31, and the other one is inserted into the receiving port 31. One of the diagnostic sockets 51 corresponds to an end of a cable, and the other one corresponds to the other end of the cable.

The front end 13 of the body unit 1 and the rear end 14 of the body unit 1 each includes an adaptor receiving portion 15, respectively. Shapes of the adaptor receiving portions 15 respectively correspond to shapes of the diagnostic adaptor heads 5. The adaptor receiving portions 15 respectively have an opening 152 inside. The transmitting port 31 and the receiving port 32 correspond to the openings 152 respectively.

In addition, the adaptor receiving portions 15 have a notch 151 respectively; the diagnostic adaptor heads 5 further have a fastening mechanism 53 respectively. The fastening mechanism 53 has a pressing portion 531 and a latching portion 532, the latching portion 532 fastens the notch 151, and the pressing portion 531 is pressed to release the latching portion 532 from the notch 151.

Furthermore, the diagnostic circuit board 33 includes a first divider resistor 331; at least one of the diagnostic adaptor heads 5 includes a second divider resistor 54. In this embodiment, each of the diagnostic adaptor heads 5 respectively includes a second divider resistor 54. When the diagnostic adaptor head 5 is electrically connected to the diagnostic circuit board 33, the first divider resistor 331 and the second divider resistor 54 are electrically connected to each other in series to produce a corresponding voltage in the diagnostic circuit board 33; whereby the diagnostic circuit board 33 can identify the diagnostic adaptor heads 5 according to pre-set data of corresponding voltages stored within the diagnostic circuit board 33.

The power unit 4 is disposed in the accommodating space 10 of the body unit 1. The power unit 4 has a battery container 41 and a power switch 42; the battery container 41 and the power switch 42 are electrically connected to the diagnostic circuit board 33.

The transmitting port 31 and the receiving port 32 respectively include twenty conductive pins, whereby the transmitting port 31 and the receiving port 32 are able to correspond to the diagnostic adaptor heads 5 having conductive pin between one and twenty.

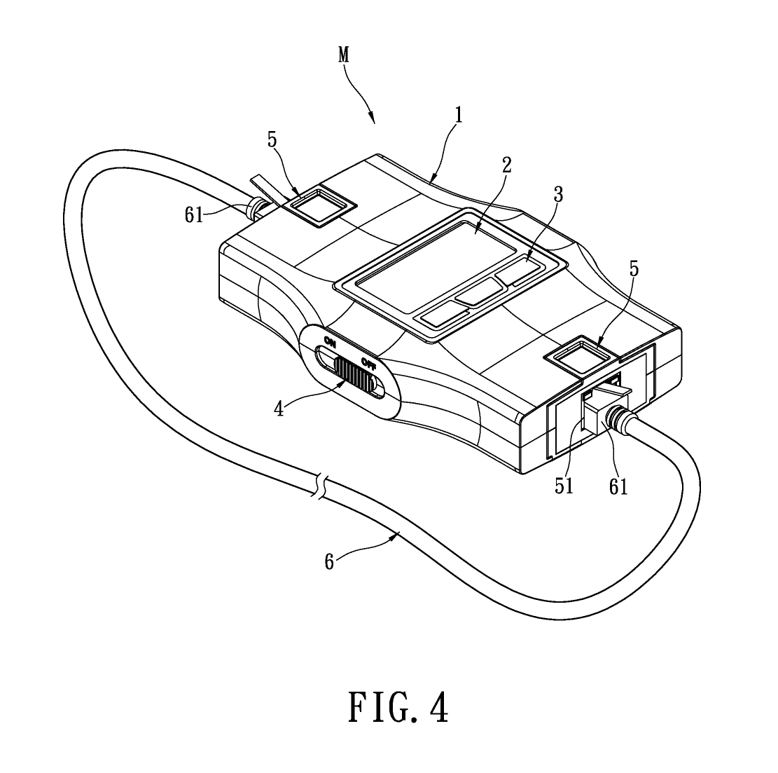

Referring now to FIG. 4, in use, both ends 61 of the diagnosed cable 6 are plugged into the diagnosing cable sockets 51 of the diagnosing adaptor heads 5 respectively. a plurality of conductive pins of the ends 61 of the cable 6 are electrically connected to the diagnostic unit 3, whereby the diagnose diagnostic unit 3 transmits and receives test pulses through the transmitting port (not shown) and receiving port (not shown) to diagnose both ends 61 of the cable 6, and the results (such as conduction, short, open or cross-line) is displayed on display unit 2.

The buttons 3 can switch the diagnosing mode to normal diagnosing mode or fast diagnosing mode.

In normal diagnosing mode, the diagnostic unit diagnoses the cable at both ends of the conductive pins. The diagnosing results displayed on the display unit in the manner of “Am-Bn”, wherein the “Am” indicates the number of “m” of the conductive pin of “A” side, “Bn” indicates the number of “n” of the conductive pin of “B” side, and “-” indicates “Am” connects to “Bn”. “A” side corresponds to the transmitting port; “B” side corresponds to the receiving port. Whereby the diagnosing results (such as conduction, short, open, or cross-line) of conductive pins of the cable can be displayed through the manner of “Am-Bn”. For example, A₀₁-B₀₁ indicates the no. 1 conductive pin of A side connecting with no. 1 conductive pin of B side, so as to confirm the conductive pins of the cable is the status of one-on-one connection. In the same way, A₀₁-B₀₁-B₀₂, indicates no. 1 conductive pin of A side, no. 1 conductive pin of B side, and no. 2 conductive pin of B side are connected, so as to confirm the conductive pins of the cable is the status of short. And A₀₁-B₀₂ indicates no. 1 conductive pin of A side connects no. 2 conductive pin of B side, so as to confirm the conductive pins of the cable is the status of cross-line.

In the fast diagnosing mode, if the diagnosing results of the cable in accordance with the results of a standard cable stored in the array of diagnostic unit, the diagnostic unit determines the status of the cable meet the status of a standard cable. The status of pass displayed on the display unit, otherwise the status of fail displayed on the display unit.

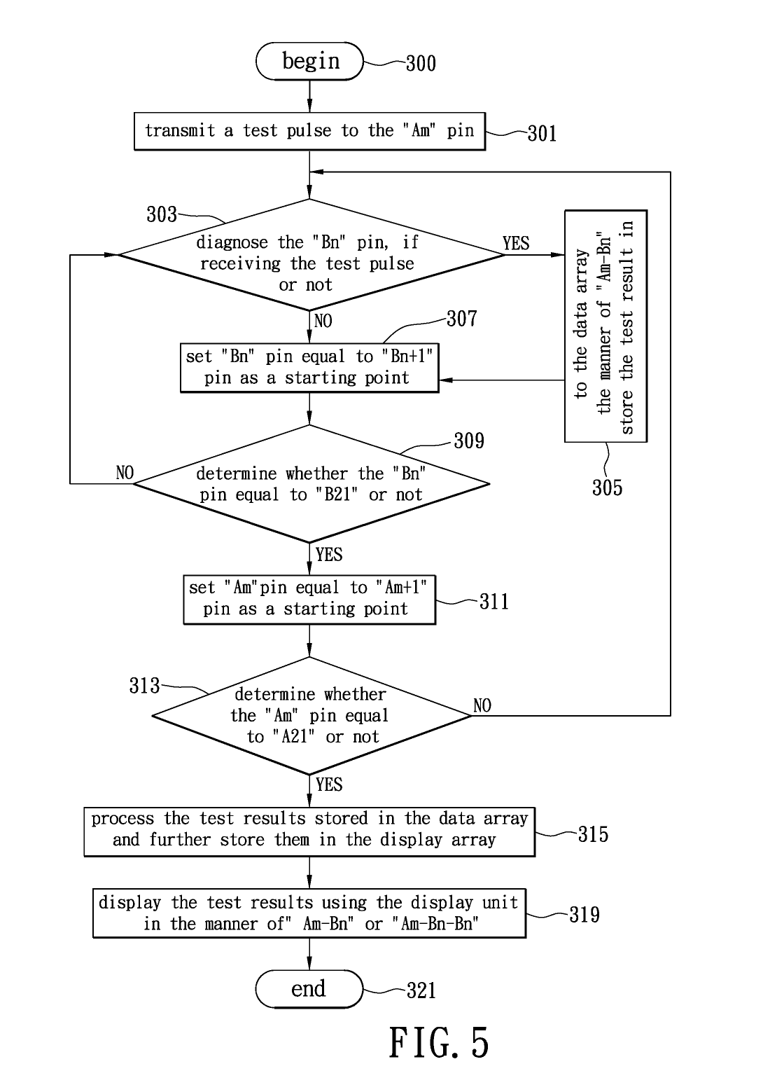

A method for diagnosing a cable status of a cable by the cable diagnosing device is shown schematically in FIG. 5. The steps for diagnosing a cable may include:

Control begins with step 300.

In step 301, control transmits a test pulse to the “Am” pin.

In step 303, control diagnoses the “Bn” pin, if receiving the test pulse or not. If so, control continues with step 305. If not, control continues with step 307.

In step 305, control stores the test results in the manner of “Am-Bn” to the data array. Then, control continues with step 307.

In step 307, control sets “Bn” pin equal to “B(n+1)” pin as a starting point. Then, control continues with step 309.

In step 309, control determines whether the “Bn” pin equal to “B₂₁” or not. If so, control continues with step 311. If not, control continues with step 303.

In step 311, control sets “Am”pin equal to “A(m+1)”pin as a starting point. control continues with step 313.

In step 313, control determines whether the “Am” pin equal to “A₂₁” or not. If so, control continues with step 315. If not, control continues with step 303.

In step 315, control processes the test results stored in the data array and further stores them in the display array.

In step S319, control displays the test results using the display unit in the manner of “Am-Bn” or “Am-Bn-Bn”.

Control ends with step 321.

The operator can be learned from the display unit for each status of the conductive pins of the cable, and quickly understand where the problem is.

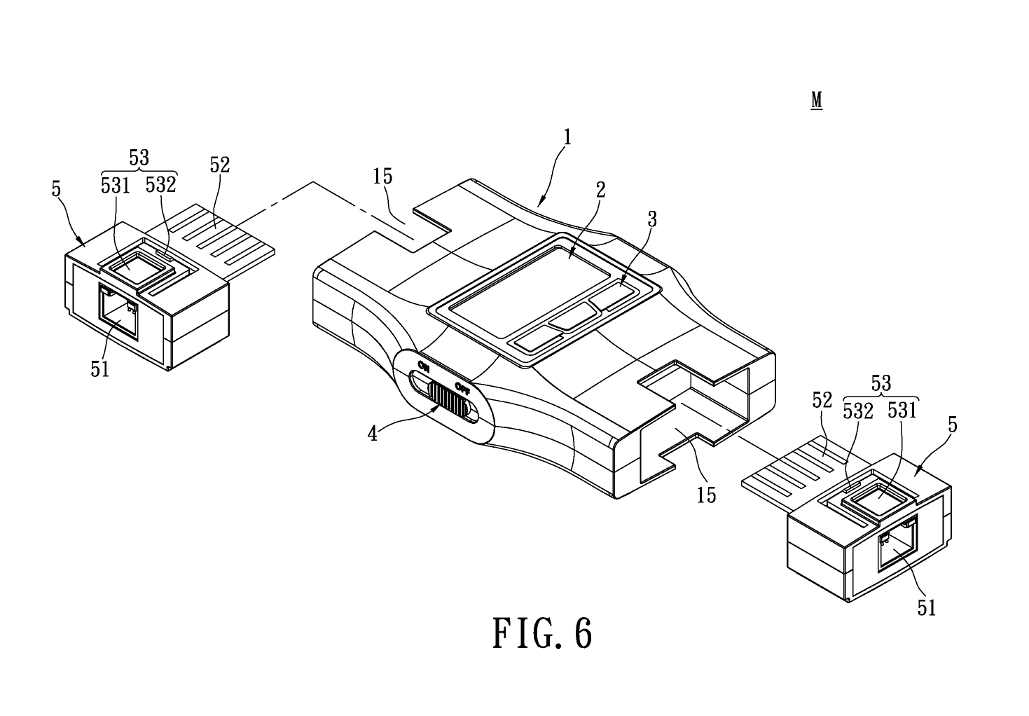

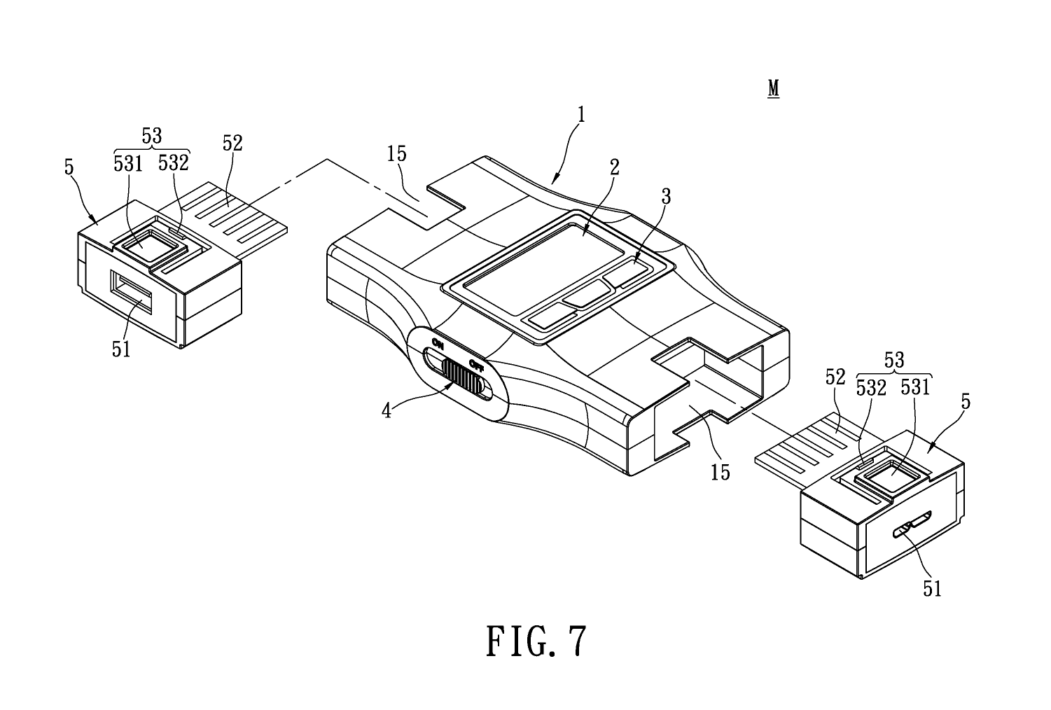

Referring now to FIGS. 6 to 7, the two diagnosing adaptor heads 5, each of them including cable socket 51 can be exactly the same RJ45 type or the different type. As shown in FIG. 7, the cable socket 51 is USB 3.0A type, and the other is USB micro AB type in order to correspond with a cable having different ends.

Furthermore, the number of conductive pins of the two ends of the cable could be different. When the different number of conductive pins of the two ends of the cable electrically connected to the diagnostic unit, the diagnostic unit determines the greatest number of conductive pins as a diagnosing benchmark. For example, a USB 3.0A to USB micro AB cable has two different ends. One of the ends is USB 3.0A, and the other is USB micro AB. The end of USB 3.0A has nine conductive pins, and the end of USB micro AB has ten conductive pins. The diagnostic unit is able to identify the number of conductive pins of the end and the other, and determines the greatest number, ten conductive pins as a diagnosing benchmark.

It is worth mentioning that there are advantages below: First, the operator can insert a pair of various diagnose adaptor heads into the cable diagnosing device corresponding to the diagnosed cable, that allows the cable diagnosing device miniaturization and easy to carry. Second, two ends of the diagnosed cable plugged into the two cable sockets of the two diagnosing adaptor heads respectively brings fast check of the diagnosed cable, which is qualified or fail. Third, the cable diagnosing device diagnoses a plurality of conductive pins of the diagnosed cable in a one-on-one manner displayed on the display unit. Thus, the status of the conductive pins of the diagnosed cable (such as conduction, open, short, or cross-line) could be determined through the display unit. The cause regarding the status of the conductive pins could be checked according to the display unit for fast diagnoses and maintains.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A cable diagnostic device, for diagnosing a plurality of conductive pins of a cable, comprising:
a body unit having an accommodating space defined therein;
a diagnostic unit disposed in the accommodating space of the body unit, the diagnostic unit including a transmitting port and a receiving port;
wherein the transmitting port and the receiving port are electrically connected to the diagnostic unit;
a display unit visibly exposed from the body unit;
a pair of diagnostic adaptor heads detachably disposed in the body unit, each of the diagnostic adaptor heads including a diagnostic connector and a diagnostic socket; whereby when the two diagnostic connectors are inserted into the transmitting port and receiving port respectively, two ends of the cable are plugged into the two diagnostic sockets respectively, the diagnostic unit diagnoses test pulses between the two ends of each conductive pins of the cable.

2. The cable diagnostic device as claimed in claim 1, wherein the display unit is a display panel or a plurality of indicators with indicating lights.

3. The cable diagnostic device as claimed in claim 1, wherein the diagnostic unit further including a diagnostic circuit board and a plurality of buttons; wherein the transmitting port, the receiving port, the display unit, and the plurality of buttons are electrically connected to the diagnostic circuit board.

4. The cable diagnostic device as claimed in claim 3, wherein the diagnostic circuit board including a first divider resistor, at least one of the diagnostic adaptor heads including a second divider resistor; wherein when the diagnostic adaptor heads are electrically connected to the diagnostic circuit board, the first divider resistor and the second divider resistor connects to each other in series.

5. The cable diagnostic device as claimed in claim 1, wherein the transmitting port and the receiving port respectively including twenty conductive pins.

6. The cable diagnostic device as claimed in claim 1, wherein the body unit including an upper shell and a lower shell, the upper shell and the lower shell jointly having a front end and a rear end of the body unit, the rear end opposite to the front end.

7. The cable diagnostic device as claimed in claim 6, wherein the front end and a rear end of the body unit respectively having a adaptor receiving portion, and shapes of the adaptor receiving portions respectively corresponding to shapes of the diagnostic adaptor heads, and the adaptor receiving portions respectively having an opening inside; wherein the transmitting port and the receiving port respectively corresponds to the openings.

8. The cable diagnostic device as claimed in claim 7, wherein the adaptor receiving portions further having a notch respectively; the diagnostic adaptor heads further having a fastening mechanism respectively; wherein the fastening mechanism having a pressing portion and a latching portion, the latching portion fastens the notch, the pressing portion is pressed to release the latching portion from the notch.

9. The cable diagnostic device as claimed in claim 1, further comprising a power unit, wherein the power unit is disposed in the accommodating space of the body unit, the power unit has a battery container and a power switch, the battery container and the power switch are electrically connected to the diagnostic unit.
